(19) United States
(12) Patent Application Publication
(10) Pub. No.: US 2012/0312344 A1
(43) Pub. Date: Dec. 13, 2012

(54) PROCESS FOR SYNTHESIZING LAYERED OXIDES

(76) Inventor: Fabian Delorme, Orleans (FR)

(21) Appl. No.: 13/578,687

(22) PCT Filed: Feb. 22, 2011
(86) PCT No.: PCT/US11/25637

§ 371 Date: Aug. 13, 2012

(30) Foreign Application Priority Data
Feb. 23, 2010 (EP) 10305175.1

(51) Int. Cl. C01F 11/02; H01L 35/28; H01L 35/22; C01G 51/04

(52) U.S. Cl. 136/201; 423/594.5; 423/594.6

(57) ABSTRACT

The present invention relates to the use of Layered Double Hydroxides (LDH) for synthesizing cobaltites, in particular Ca₃Co₄O₉. The invention also relates to a thermoelectric material comprising Ca₃Co₄O₉ as obtained from a LDH precursor.

### CROSS REFERENCE TO RELATED APPLICATION

This application claims the benefit of priority to European Patent Application No. 10305175.1, filed on Feb. 23, 2010.

### TECHNICAL FIELD OF THE INVENTION

The present invention relates to a process for synthesizing layered oxides with CdI₂-type layers, and to the use of the resulting oxides as thermoelectric materials.

### BACKGROUND OF THE INVENTION

The existence of a global warming has now been largely demonstrated. The anthropic origin of this global warming is also accepted and the effect of greenhouse gas has been pointed out. Among greenhouse gas, the effect of CO₂ is preponderant, not because of a high greenhouse effect potential, which is in fact moderate, but due to the high amounts of CO₂ produced by various human activities (energy production, transportation, concrete synthesis etc.). The limitation of CO₂ emissions in order to limit the global warming is definitively one of the main objectives of the XXI^{st} century. For large fixed emitters such as power plants or factories, solutions such as capture and geological storage, can be considered as efficient. However these techniques cannot be considered for small mobile emitters such as vehicles. For these small emitters, it is necessary to reduce as low as possible the CO₂ emissions.

Different solutions to reduce fuel consumption and CO₂ emissions are developed by the automobile industry. One of the most interesting solutions for short term applications is to use a thermoelectric device to produce electricity from the engine waste heat. Indeed, vehicles require more and more electricity for different security and comfort devices, whereas more than 30% of the energy produced from the fuel is lost as waste heat. Thus, the electricity required for the different applications of the vehicle would be produced from the thermoelectric device, leading to decreased fuel consumption and consequently to decreased CO₂ emissions.

Thermoelectric materials, discovered in 1821, are solids that produce an electric current when joined together and subjected to a temperature difference across the junction. Fundamentally, thermoelectricity is concerned with the so-called Seebeck and Peltier effects. The first of these arises because of the property of certain materials, which creates an electrical potential V (expressed in Volts) between the ends of a solid submitted to a thermal gradient ΔT (expressed in degrees Kelvin). The Seebeck coefficient (S) is a measure of this induced electrical potential per the equation:

S=V/ΔT

and is usually expressed in μV/K.

The Seebeck coefficient may be positive (p material) or negative (n material) depending on the nature and mobility of the charge carriers in the solid. This property is generally used to collect electrical energy from sources of heat. The Peltier effect is the opposite phenomenon, namely the creation of a temperature gradient in a material submitted to an electrical potential. It is generally exploited in cooling devices. For energy production, several pairs of n and p materials must usually be assembled in series in order to produce enough voltage for the required application.

From the material point of view, the properties required to allow making an efficient thermoelectric generator are:
a high Seebeck S absolute value either for p (+) or n (−) material for a significant voltage;
a high electrical conductivity σ, in order to deliver enough intensity;
a low thermal conductivity κ, in order to maintain the thermal gradient at the origin of the voltage obtained.

To express the combination of the requirements on the three previously defined parameters, a figure of merit (ZT) of a material can be expressed in the form of:

$$ZT = \frac{{S}^{2} σ}{κ} ,$$

where S is the Seebeck coefficient of the material (V/K), σ is the electrical conductivity of the material (A/V.m) and κ is the thermal conductivity of the material (W/m.K).

Materials presenting a ZT>1, such as BiTe, PbTe, Skutterudites (CoSb₃) or Mg₂Si, are considered for applications in motor vehicles.

However, using thermoelectric materials within a vehicle engine requires resistance at high temperature (700-800° C.) under oxidizing conditions (air atmosphere). Most of the materials presenting high ZT values are not stable in these conditions. Oxides appear as promising candidates as most of them are stable in these conditions. Moreover, the discovery of a large thermopower in the metallic oxide NaₓCoO₂ (Terasaki et al. 1997) has started an intense international research activity in the field of thermoelectric oxides.

Among all the oxides studied, layered oxides have shown high thermoelectric properties. Indeed ZT values close to 1 for single crystals have been reported for NaₓCoO₂ (Terasaki et al. 1997), Ca₃Co₄O₉ (Shikano et al. 2003) or Bi₂Sr₂Co₂O_{y} (Funahashi et al. 2002). All these layered oxides present CdI₂-type layers (these layers refer to a crystallographic type of 2D planes composed by edge sharing octahedra). These layers can be separated by cations as in NaₓCoO₂ (Terasaki et al. 1997, op. cit.) or delafossites (Koumoto et al. 2001; Guilmeau et al. 2009), or by a various number of rocksalt layers such as in Ca₃Co₄O₉ (Shikano et al. 2003, op. cit.) or Bi₂Sr₂Co₂O_{y} (Funahashi et al. 2002, op. cit.).

Different techniques have been proposed to synthesise these layered oxides with CdI₂-type layers. The most classical synthesis route is the standard solid state reaction of a mix of oxides and/or salts of each of the different constituting cations. For example, Ca₃Co₄O₉ is usually prepared from CaCO₃ and Co₃O₄ (Miyazaki et al. 2000), and less frequently from CaCO₃ and Co₂O₃ (Li et al. 1999), CaO and Co₃O₄ (Masset et al. 2000), or CaCO₃ and CoO (Liu et al. 2006). It has recently been proposed to synthesise layered oxides by the sol-gel method (Li et al. 2005) or by co-precipitation of oxalates (Zhang et al. 2008). The synthesis of the Ca₃Co₄O₉ phase using an in situ topotactic conversion of aligned platelet particles of Co(OH)₂ has been recently reported (Tani et al. 2003; U.S. Pat. No. 6,806,218).

### SUMMARY OF THE INVENTION

Conventional processes for preparing oxides with CdI₂-type layers appear to be limited in the choice of the metal precursors that can be used. The present invention is based on the discovery that Layered Double Hydroxides (LDH) can be used as precursors of layered cobaltites without impacting, and even improving, the thermoelectric properties thereof.

A first aspect of the invention therefore relates to the use of a Layered Double Hydroxide (LDH) for synthesizing layered cobaltites.

Another aspect of the invention relates to a thermoelectric material comprising a layered cobaltite obtained from a LDH.

A further aspect of the invention relates to a thermoelectric device comprising the aforementioned thermoelectric material.

### BRIEF DESCRIPTION OF THE DRAWINGS

FIG. 1 shows the structure of different layered oxides, from left to right: CdI₂-type layers separated by cations, by 2 rocksalt layers, by 3 rocksalt layers or by 4 rocksalt layers.

FIG. 2 shows the structure of Layered Double Hydroxides.

FIG. 3 shows X-ray diffraction patterns of two Co^{II}Co^{III}-LDH precursors of the invention, and of β-Co(OH)₂.

FIG. 4 shows X-ray diffraction patterns of a layered cobaltite, Ca₃Co₄O₉, synthesized from a LDH precursor and from a conventional mix of oxides and carbonates.

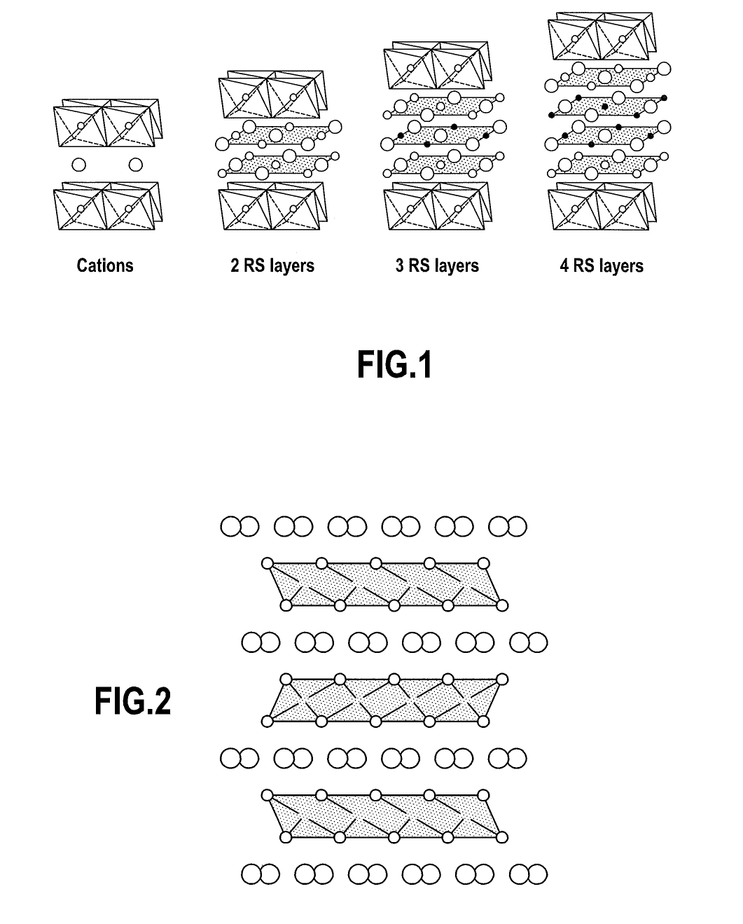

### DETAILED DESCRIPTION OF THE INVENTION

The present invention provides a new route for the synthesis of layered cobaltites with CdI₂-type layers, wherein a Layered Double Hydroxide is used as a precursor of the cobaltites.

Layered Double Hydroxides (LDHs) are a wide family of compounds, also known as anionic clays or hydrotalcite-like compounds. A review of LDHs has been published by Cavani et al. in 1991.

Within the context of the present invention, the terms ‘cobaltite’ or ‘layered cobaltite’, are intended to mean oxides of cobalt and at least another metal element, said oxides having a CdI₂-type layered structure. Typical examples of cobaltites include, but are not limited to, MₐCoO₂ where M is an alkaline metal, Ca₃Co₄O₉ and Bi₂Sr₂Co₂O_{b}.

In one aspect, the invention therefore relates to the use of a Layered Double Hydroxide for synthesizing a layered cobaltite.

The Layered Double Hydroxide (LDH) can be represented by the following formula (I) or (II):

[M1₁₋ₓCOₓ(OH)₂]^{(2x-1)+}[Aⁿ⁻]_{(2x-1)/n}.mH₂O (I)

[M2₁₋ₓM3ₓ(OH)₂]^{x+}[Aⁿ⁻]_{x/n}.mH₂O (II)

in which:
M1 is a monovalent metal, M2 is a divalent metal, M3 is a trivalent metal, A is an anion,
x is such that 0.1≦x≦0.5, and
at least one of M2 and M3 is cobalt.

In the above formulae (I) and (II), m represents the number of water molecules which result from the synthesis of the LDH. This number can vary depending on the technique and operating conditions used.

Suitable monovalent metals which can used as metal M1 include Na, Li, K. M1 is preferably Na or Li, more preferably Na.

Suitable divalent metals which can used as metal M2 include Mg, Ca, Mn, Zn, Co, Cd, Cu and Ni. M2 is preferably Co or Ca.

Suitable trivalent metals which can be used as metal M3 include Co, Al, Fe, Cr and Ga. M3 is preferably Co.

Representative examples of LDHs which can be used in the present invention thus include those of formula (II) where M2 is Co^{II} and M3 is Co^{III} and those where M2 is Ca and M3 is Co^{III}.

The anion can be an inorganic anion such as chloride, fluoride, bromide, nitrate, sulfonate, carbonate or hydroxide (see e.g. Miyata 1983) or can be as complex as DNA (see e.g. Choy 2004). The anion is preferably an inorganic anion such as nitrate, hydroxide or carbonate.

In one embodiment, the precursor of the cobaltite comprises a mixture of a LDH of formula (I) as defined above and a source of metal M1 wherein M1 is as defined above.

In another embodiment, the precursor of the cobaltite comprises a mixture of a LDH of formula (II) as defined above and a source of metal M2 or M3 wherein M2 and M3 are as defined above.

Suitable sources of metals M1, M2 and M3 include carbonates, salts or hydroxides of said metals.

In yet another embodiment, the precursor of the cobaltite comprises a mixture of a LDH of formula (II) as defined above and another LDH of formula (III):

[M2₁₋ₓM3ₓ(OH)₂]^{x+}[Aⁿ⁻]_{x/n}.mH₂O (III)

in which M2, A and x are as defined above for formula (I) and M3 is cobalt.

LDHs can be prepared by methods known in the art, for example following the procedure described by Cavani et al. (op. cit.) or Hu et al. (2009).

As explained above, cobaltites have a CdI₂-type layered structure. LDHs are presenting a similar structure that can be used as a template of the layered oxide structure.

In addition, LDHs are usually coprecipitated as nanoparticles, i.e. nano-sub-hexagonal-plate-like particles with a particle size close to 50 nm in the (a,b) planes and a few tenth or hundred of Å along the c-axis. Layered oxides obtained from traditional synthesis routes present a similar plate-like morphology but with higher dimensions (usually a few microns in the (a,b) planes and hundred of nm along the c-axis). The use of LDHs as precursors allows smaller layered oxide particles to be obtained which in turn will lead to a decrease in thermal conductivity and thus to an increase in ZT. This proves to be of interest in the synthesis of thermoelectric materials, in particular Ca₃Co₄O₉.

Thus, according to another aspect, the present invention relates to a process for synthesizing a cobaltite of formula Ca₃Co₄O₉, which comprises the step of heat treating a mixture of:

(i) a LDH of formula (IIIa):

[M2₁₋ₓM3ₓ(OH)₂]^{X+}[Aⁿ⁻]_{x/n}.mH₂O (IIIa)

in which:
M2 and M3 each are Co, A is an anion, and
x is such that 0.1≦x≦0.5, and
(ii) either a source of calcium or a LDH of formula (IIIb)

[M2₁₋ₓM3ₓ(OH)₂]^{x+}[Aⁿ⁻]_{x/n}.mH₂O (IIIb)

in which:
M2 is Ca, M3 is Co, A is an anion, and
x is such that 0.1≦x≦0.5.

The LDH of formula (IIIa) and either the source of calcium or the LDH of formula (IIIb) are preferably used in stoichiometric amounts. These materials are mixed before the heat treatment takes place. Mixing can be carried out e.g. in a tumble or by attrition according to methods well known to the skilled person. A preferred source of calcium is CaCO₃.

In one embodiment, the heat treatment can be carried out in two steps: the mixed precursors are first heated at a temperature of between about 700° C. and about 950° C., and then sintered at a temperature of between about 700° C. and about 1100° C., preferably at a temperature of between about 800° C. and about 1050° C. Various sintering techniques can be used such as conventional sintering, hot pressing or spark plasma sintering.

In another embodiment, the heat treatment can be carried out by means of reactive sintering such as, for example, spark plasma sintering.

The resulting Ca₃Co₄O₉ has a positive Seebeck coefficient and can be used as a thermoelectric material.

Thermoelectric devices comprise a thermoelectric material of the n-type (having a negative Seebeck coefficient) and a thermoelectric material of the p-type (having a positive Seebeck coefficient). The p-type thermoelectric material of the present invention can be used as a part of a thermoelectric device.

In another aspect, the present invention therefore relates to a thermoelectric device comprising a thermoelectric material as defined above. One of the most interesting short term applications of thermoelectric devices is waste heat recovery, in particular waste heat recovery of automobile engines. Indeed, vehicles require more and more electricity for different security and comfort devices, whereas more than 30% of the energy produced from the fuel is lost as waste heat. Waste heat recovery can be used to produce electricity using a thermoelectric device, leading to decreased fuel consumption and consequently to decreased CO₂ emissions.

The invention is illustrated by the examples below. In these examples, the following techniques were used to characterize the LDH and layered cobaltites of the invention.

Sintering was performed by Spark Plasma Sintering (SPS, FCT Systeme GmbH HP D 25). The synthesised powders were placed in a 20 mm diameter graphite die. A pressure of 70 MPa was applied whereas the temperature was raised at 100° C./min up to 850° C. for 5 minutes. Then the sample was cooled at 100° C./min to room temperature. The obtained pellets were then polished to remove the graphite foils used during the SPS process and cut as bars for thermoelectric properties measurements or core drilled (12.7 mm diameter, 2 mm in thickness) for thermal conductivity measurements.

Thermoelectric properties of the sintered samples were determined from simultaneous measurement of resistivity and Seebeck coefficient in a ZEM III equipment (ULVAC Technologies) and of thermal conductivity. The thermal conductivity, κ, was determined from thermal diffusivity, a, heat capacity, Cₚ, and density ρ, using the following equation: κ=ρ a Cₚ. The thermal diffusivity was measured using the laser flash diffusivity technique (Netzsch LFA 427) from room temperature to 800° C. in air atmosphere. The thermal diffusivity measurement of all specimens was carried out three times at each temperature. The heat capacity of the materials was measured from room temperature to 800° C., with a heating rate of 10° C.min⁻¹ in platinum crucibles and in air atmosphere, using differential scanning calorimetry (Netzsch DSC 404 C pegasus).

Powder X-ray diffraction (XRD) patterns have been performed on a Philips X'PERT Pro θ/2θ diffractometer equipped with an X'CELERATOR real time multiple strip detector, using Cu—K_{α} radiation and operating at 45 kV and 40 mA at room temperature. The scans have been recorded from 5 to 140° (20) with a step of 0.00167° and a counting time of 40s per step.

### Example 1

### Synthesis of a Co^{II}Co^{III} LDH

An aqueous solution was prepared, containing 0.01 mole of cobalt nitrate (Co(NO₃)₂.6H₂O, VWR, 99.7% purity) and 10 g of PEG (Aldrich) in 50 ml of water. A 20% NH₃ solution (Fischer) was added dropwise to the above-mentioned aqueous solution at a constant rate through a peristaltic pump, according to the varying pH method (as described in Journal of Physics and Chemistry of Solids 2008, 69(5-6), 1088-1090). The pH was monitored by a pH-meter (Mettler DL67 Titrator) and the experiment was stopped when the pH reached a value of 9.

The resulting slurry was aged under vigorous stirring during 24 h at room temperature, and then centrifuged at 4000 rpm during 5 min (Eppendorf Centrifuge 5403). The supernatant was removed and the residue was washed three times with deionized water at room temperature, then dried overnight in a furnace at 60° C. (Binder).

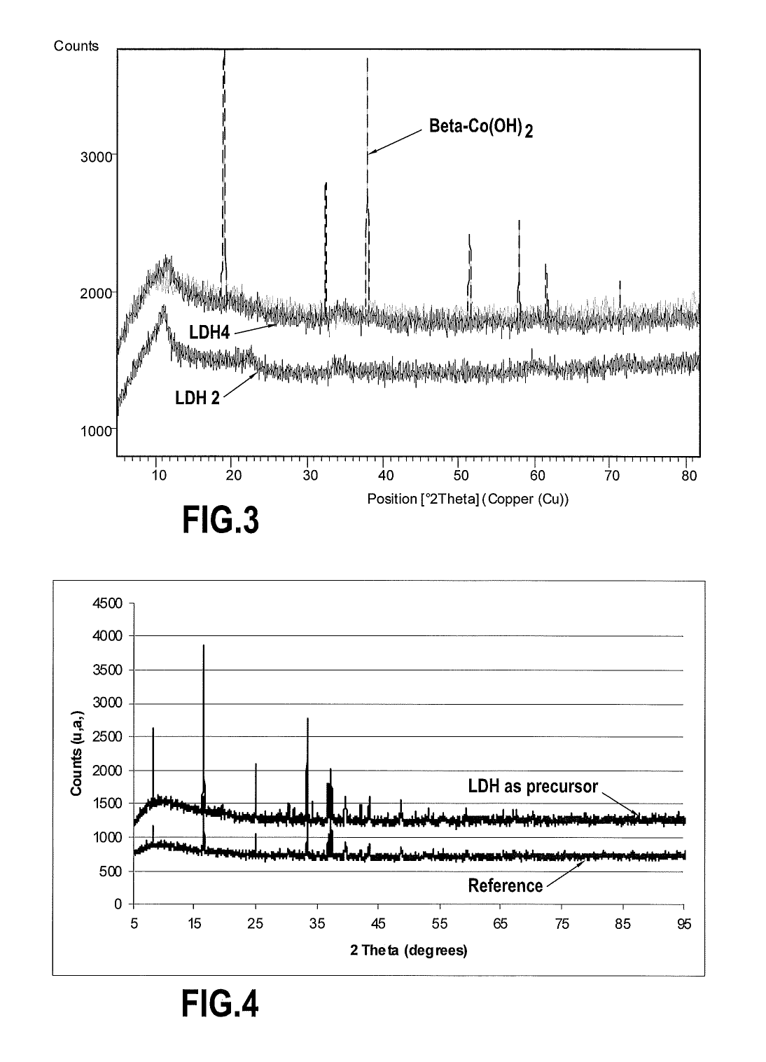

FIG. 3 shows the X-ray diffraction pattern of the resulting powder (LDH2), compared to that of β-Co(OH)₂ used as a reference. The powder has a pattern which does not have the structure of β-Co(OH)₂ but rather has the layered structure of a layered double hydroxide (as recently evidenced by Hu et al. 2009, op. cit.).

### Example 2

### Synthesis of a Co^{II}Co^{III} LDH

A first aqueous solution was prepared, containing 0.01 mole of cobalt nitrate (Co(NO₃)₂.6H₂O, VWR, 99.7% purity) in 50 ml of water. A second solution was prepared by introducing 280 ml of a 3.5 M NaOH solution (solid NaOH from Fischer (98%)) in 1000 ml of a 1M Na₂CO₃ solution (Merck, 99.5%). The second solution was added dropwise to the first solution at a constant rate through a peristaltic pump, according to the varying pH method (as described in Journal of Physics and Chemistry of Solids 2008, 69(5-6), 1088-1090). The pH was monitored by a pH-meter (Mettler DL67 Titrator) and the experiment was stopped when the pH reached a value of 9.

The resulting slurry was aged under vigorous stirring during 24 h at room temperature, and then centrifuged at 4000 rpm during 5 min (Eppendorf Centrifuge 5403). The supernatant was removed and the residue was washed three times with deionized water at room temperature, then dried overnight in a furnace at 60° C. (Binder).

FIG. 3 shows the X-ray diffraction pattern of the resulting powder (LDH4), compared to that of β-Co(OH)₂ used as a reference. The powder has a pattern which does not have the structure of β-Co(OH)₂ but rather has the layered structure of a layered double hydroxide (as recently evidenced by Hu et al. 2009, op. cit.).

### Example 3

### Synthesis of Ca₃Co₄O₉

Stoichiometric amounts of the Co^{II}Co^{III} LDH of example 2 and of CaCO₃ (Sigma Aldrich, >99% purity) were thoroughly mixed for 5 min at 400 rpm in an agate ball mill (Retsch PM 100). The resulting powder was heated at 850° C. for 8 h in an alumina crucible at a rate of 5° C./min and then slowly cooled down, whereby a powdered oxide was obtained. Sintering was then performed by Spark Plasma Sintering (SPS, FCT Systeme GmbH HP D 25) as follows. The powdered oxide was placed in a 20 mm diameter graphite die. A pressure of 70 MPa was applied whereas the temperature was raised at 100° C./min up to 850° C. for 5 minutes. Then the sample was cooled at 100° C./min to room temperature. The obtained pellets were then polished to remove the graphite foils used during the SPS process and cut as bars for thermoelectric properties measurements or core drilled (12.7 mm diameter, 2 mm in thickness) for thermal conductivity measurements.

FIG. 4 shows that this oxide exhibits a Ca₃Co₄O₉ phase, demonstrating that the Co^{II}Co^{III} LDH is a suitable precursor for the synthesis of the layered oxide Ca₃Co₄O₉.

### Example 4

### Thermoelectric Properties of Ca₃Co₄O₉

The thermoelectric properties of the oxide of example 3 were compared to those of Ca₃Co₄O₉ obtained by conventional mixing of CaCO₃ (Sigma Aldrich, >99% purity) with either Co₃O₄ having an average particle size of the order of a few micrometers (Sigma Aldrich; reference example 1) or Co₃O₄ having an average particle size of a few nanometers (Sigma Aldrich, 99.8% purity; reference example 2), and subsequent heating of the resulting mixture. Samples were sintered under the conditions described in example 3. The results are presented in the table below.

| | Power Factor | Kappa | ZT |
|---|---|---|---|
| Example 2 | 3.07 10⁻⁴ | 1.67 | 1.83 10⁻¹ |
| Ref. Example 1 | 3.14 10⁻⁴ | 2.10 | 1.50 10⁻¹ |
| Ref. Example 2 | 3.20 10⁻⁴ | 1.70 | 1.90 10⁻¹ |

1. Use of a Layered Double Hydroxide (LDH) for synthesizing a cobaltite, wherein the LDH has the following formula (I) or (II):
[M1₁₋ₓCoₓ(OH)₂]^{(2x-1)+}[Aⁿ⁻]_{(2x-1)/n}.mH₂O (I)
[M2₁₋ₓM3ₓ(OH)₂]^{x+}[Aⁿ⁻]_{x/n}.mH₂O (II)
in which:
M1 is a monovalent metal, M2 is a divalent metal, M3 is a trivalent metal, A is an anion,
x is such that 0.1≦x≦0.5, and
at least one of M2 and M3 is cobalt.

2. Use according to claim 1, wherein M1 is selected from Na, Li and K; M2 is selected from Mg, Ca, Mn, Zn, Co, Cd, Cu and Ni; and M3 is selected from Co, Al, Fe, Cr and Ga.

3. Use according to claim 1 or 2 of a LDH of formula (I) wherein M1 is Na.

4. Use according to claim 1 or 2 of a LDH of formula (II) wherein M2 is selected from Co and Ca and M3 is Co.

5. A process for synthesizing a cobaltite of formula Ca₃Co₄O₉, which comprises the step of heat treating a mixture of:
(i) a LDH of formula (IIIa):
[M2₁₋ₓM3ₓ(OH)₂]^{x+}[Aⁿ⁻]_{x/n}.mH₂O (IIIa)
in which:
M2 and M3 each are Co, A is an anion, and
x is such that 0.1×0.5, and
(ii) either a source of calcium or a LDH of formula (IIIb)
[M2₁₋ₓM3ₓ(OH)₂]^{x+}[Aⁿ⁻]_{x/n}.mH₂O (IIIb)
in which:
M2 is Ca, M3 is Co, A is an anion, and
x is such that 0.1≦x≦0.5.

6. The process according to claim 5, wherein the source of calcium is CaCO₃.

7. Use of a cobaltite of formula Ca₃Co₄O₉ obtained by the process of claim 5 or 6 as a thermoelectric material.

8. A thermoelectric device comprising a thermoelectric material as defined in claim 7.

9. Use of the thermoelectric device of claim 8 for the waste heat recovery of automobile engines

10. A method for recovering waste heat from automobile engines wherein a thermoelectric device as defined in claim 8 is used.
